(19) United States
(12) Patent Application Publication
(10) Pub. No.: US 2025/0266698 A1
(43) Pub. Date: Aug. 21, 2025

(54) Traction Battery Controller Employing Refined State-of-Charge Uncertainty Bound in Estimating Capacity of Traction Battery

(71) Applicant: Ford Global Technologies, LLC, Dearborn, MI (US)

(72) Inventors: Donnell Matthew Washington, Northville, MI (US); Yonghua Li, Ann Arbor, MI (US); Michael David Beeney, Canton, MI (US)

(73) Assignee: Ford Global Technologies, LLC, Dearborn, MI (US)

(21) Appl. No.: 18/581,003

(22) Filed: Feb. 19, 2024

(51) Int. Cl. H02J 7/00; G01R 31/367; G01R 31/3828; G01R 31/3842; G01R 31/396

(52) U.S. Cl. CPC H02J 7/0048; G01R 31/367; G01R 31/3828; G01R 31/3842; G01R 31/396

(57) ABSTRACT

A system includes a battery and a controller. The battery has a state-of-charge (SOC) with a SOC uncertainty. The controller is configured to charge and discharge the battery based on a capacity of the battery according to the SOC with a bound of the SOC uncertainty. The bound of the SOC uncertainty is based on consideration of multiple SOC uncertainty factors to thereby be reduced relative to being based on consideration of less than all of the SOC uncertainty factors.

### TECHNICAL FIELD

The present disclosure relates to detecting a capacity of a traction battery of an electrified vehicle for use in controlling the operation of the traction battery and/or the vehicle.

### BACKGROUND

An electrified vehicle includes a traction battery for providing power to a motor of the vehicle to propel the vehicle. Operating characteristics of the traction battery, such as its charge capacity, may be monitored for use in controlling the operation of the traction battery and/or the vehicle.

### SUMMARY

A system includes a battery and a controller. The battery has a state-of-charge (SOC) with a SOC uncertainty. The controller is configured to charge and discharge the battery based on a capacity of the battery according to the SOC with a bound of the SOC uncertainty. The bound of the SOC uncertainty (i.e., the SOC uncertainty bound) is based on consideration of multiple SOC uncertainty factors to thereby be reduced relative to being based on consideration of less than all of the SOC uncertainty factors.

In embodiments, each SOC uncertainty factor is associated with its own bound of the SOC uncertainty. The bound of the SOC uncertainty is the smallest bound of the SOC uncertainty factors.

In embodiments, each SOC uncertainty factor is associated with its own bound of the SOC uncertainty and the bound of each SOC uncertainty factor is a range between a negative value and a positive value. The bound of the SOC uncertainty is a range between (i) the negative value having a lowest magnitude amongst the negative values and (ii) the positive value having a lowest magnitude amongst the positive values.

A first one of the SOC uncertainty factors may be indicative of the SOC uncertainty based on an uncertainty of a voltage measurement of the battery and a SOC-OCV (open-circuit voltage) table that are used together in estimating the SOC. The bound of the SOC uncertainty is reduced relative to being based on consideration of just the first one of the SOC uncertainty factors. Another one of the SOC uncertainty factors may be indicative of the SOC uncertainty based on a range of an amount of SOC uncertainty that is physically possible. Another one of the SOC uncertainty factors may be indicative of the SOC uncertainty based on an uncertainty of an ampere-hour integration measurement that is used in estimating the SOC. Another one of the SOC uncertainty factors may be indicative of the SOC uncertainty based on distributed voltage measurements of the battery that are used in estimating the SOC. Another one of the SOC uncertainty factors may be indicative of the SOC uncertainty based on an uncertainty pertaining to differences of a SOC-OCV (open-circuit voltage) table at different voltage measurements in which the SOC-OCV table with the different voltage measurements are used in estimating the SOC.

A method includes detecting a SOC of a battery, estimating an uncertainty of the SOC based on consideration of multiple SOC uncertainty factors, and detecting a capacity of the battery according to the SOC with the estimated SOC uncertainty. The estimated SOC uncertainty is reduced relative to an uncertainty of the SOC estimated based on consideration of less than all of the SOC uncertainty factors such that the capacity has reduced uncertainty. The method further includes charging and discharging the battery based on the capacity.

An electrified vehicle includes a traction battery and a controller. The controller is configured to detect a SOC of the traction battery and to estimate an uncertainty of the SOC based on consideration of multiple SOC uncertainty factors. The estimated SOC uncertainty is reduced relative to an uncertainty of the SOC estimated based on consideration of less than all of the SOC uncertainty factors. The controller is configured to charge and discharge the traction battery based on a capacity of the traction battery according to the SOC with the estimated SOC uncertainty.

### BRIEF DESCRIPTION OF THE DRAWINGS

FIG. 1 illustrates a block diagram of a battery electric vehicle (BEV);

FIG. 2 illustrates a block diagram of an arrangement for a traction battery controller of the BEV to monitor a traction battery of the BEV;

FIG. 3 illustrates a block diagram of the traction battery controller, the traction battery controller including a capacity estimator for estimating a capacity of the traction battery according to a state-of-charge (SOC) of the traction battery;

FIG. 4 illustrates a block diagram depictive of SOC uncertainty factors considered by the traction battery controller in estimating an SOC uncertainty bound for the SOC of the traction battery;

FIG. 5 illustrates a graph of exemplary values for the SOC uncertainty factors considered by the traction battery controller in estimating the SOC uncertainty bound; and

FIG. 6 illustrates a flowchart depicting operation of the traction battery controller in controlling the traction battery and/or the vehicle based on the capacity of the traction battery according to the SOC of the traction battery with the estimated SOC uncertainty bound.

### DETAILED DESCRIPTION

Detailed embodiments of the present disclosure are disclosed herein; however, it is to be understood that the disclosed embodiments are merely exemplary of the present disclosure that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

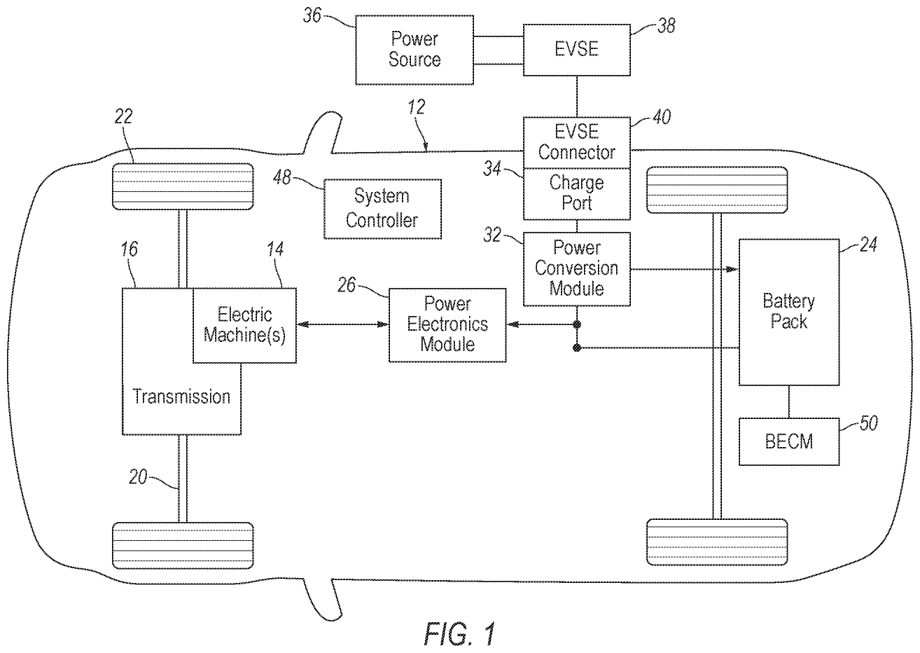

Referring now to FIG. 1, a block diagram of an electrified vehicle (EV) 12 in the form of a battery electric vehicle (BEV) is shown. BEV 12 includes a powertrain having one or more traction motors (“electric machine(s)”) 14, a traction battery (“battery” or “battery pack”) 24, and a power electronics module 26 (e.g., an inverter). In the BEV configuration, traction battery 24 provides all of the propulsion power and the vehicle does not have an engine. In other variations, the EV may be a plug-in or regular hybrid electric vehicle (PHEV, HEV) further having an engine.

Traction motor 14 is part of the powertrain of BEV 12 for powering movement of the BEV. In this regard, traction motor 14 is mechanically connected to a transmission 16 of BEV 12. Transmission 16 is mechanically connected to a drive shaft 20 that is mechanically connected to wheels 22 of BEV 12. Traction motor 14 can provide propulsion capability to BEV 12 and is capable of operating as a generator. Traction motor 14 acting as a generator can recover energy that may normally be lost as heat in a friction braking system of BEV 12.

Traction battery 24 stores electrical energy that can be used by traction motor 14 for propelling BEV 12. Traction battery 24 typically provides a high-voltage (HV) direct current (DC) output. Traction battery 24 is electrically connected to power electronics module 26. Traction motor 14 is also electrically connected to power electronics module 26. Power electronics module 26, such as an inverter, provides the ability to bi-directionally transfer energy between traction battery 24 and traction motor 14. For example, traction battery 24 may provide a DC voltage while traction motor 14 may require a three-phase alternating current (AC) current to function. Inverter 26 may convert the DC voltage to a three-phase AC current to operate traction motor 14. In a regenerative mode, inverter 26 may convert three-phase AC current from traction motor 14 acting as a generator to DC voltage compatible with traction battery 24.

In addition to providing electrical energy for propulsion of BEV 12, traction battery 24 may provide electrical energy for use by other electrical systems of the BEV including HV loads such as electric heater and air-conditioner systems, and low-voltage (LV) loads such as an auxiliary battery.

Traction battery 24 is rechargeable by an external power source 36 (e.g., the grid). External power source 36 may be electrically connected to electric vehicle supply equipment (EVSE) 38. EVSE 38 provides circuitry and controls to control and manage the transfer of electrical energy between external power source 36 and BEV 12. External power source 36 may provide DC or AC electric power to EVSE 38. EVSE 38 may have a charge connector 40 for plugging into a charge port 34 of BEV 12. A power conversion module 32 of EV 12, such as an on-board charger having a DC/DC converter, may condition power supplied from EVSE 38 to provide the proper voltage and current levels to traction battery 24. Power conversion module 32 may interface with EVSE 38 to coordinate the delivery of power to traction battery 24.

The various components described above may have one or more associated controllers to control and monitor the operation of the components. The controllers can be microprocessor-based devices. The controllers may communicate via a serial bus (e.g., Controller Area Network (CAN)) or via discrete conductors.

For example, a system controller 48 (“vehicle controller”) is present to coordinate the operation of the various components. Controller 48 includes electronics, software, or both, to perform the necessary control functions for operating BEV 12. Controller 48 may be a combination vehicle system controller and powertrain control module (VSC/PCM). Although controller 48 is shown as a single device, controller 48 may include multiple controllers in the form of multiple hardware devices, or multiple software controllers with one or more hardware devices. In this regard, a reference to a “controller” herein may refer to one or more controllers.

Controller 48 implements a battery energy control module (BECM) 50. BECM 50 is in communication with traction battery 24. BECM 50 is a traction battery controller operable for managing the charging and discharging of traction battery 24 and for monitoring operating characteristics of the traction battery. BECM 50 is operable to implement algorithms to detect (e.g., estimate) the operating characteristics of traction battery 24. BECM 50 controls the operation and performance of traction battery 24 based on the operating characteristics of the traction battery. The operation and performance of other systems and components of BEV 12 may be controlled by BECM 50 and/or other controllers of the BEV based on the operating characteristics of traction battery 24.

Operating characteristics of traction battery 24 include its charge capacity (“capacity”) and its state-of-charge (SOC). The capacity of traction battery 24 is indicative of the maximum amount of electrical energy that the traction battery may store. The SOC of traction battery 24 is indicative of a present amount of electrical charge stored in the traction battery. The SOC of traction battery 24 may be represented as a percentage of the maximum amount of electrical charge that may be stored in the traction battery (i.e., as a percentage of the capacity). BECM 50 may output the SOC of traction battery 24 to inform the driver of BEV 12 how much charge remains in the traction battery, similar to a fuel gauge.

Another operating characteristic of traction battery 24 is its power capability. The power capability of traction battery 24 is a measure of the maximum amount of power the traction battery can provide (i.e., discharge) or receive (i.e., charge) for a specified time period. As such, the power capability of traction battery 24 corresponds to discharge and charge power limits which define the amount of electrical power that may be supplied from or received by the traction battery at a given time. These limits can be provided to other vehicle controls, for example, through a vehicle system controller (VSC), so that the information can be used by systems that may draw power from or provide power to traction battery 24. Vehicle controls are to know how much power traction battery 24 can provide (discharge) or take in (charge) in order to meet the driver demand and to optimize the energy usage. As such, knowing the power capability of traction battery 24 allows electrical loads and sources to be managed such that the power requested is within the limits that the traction battery can handle.

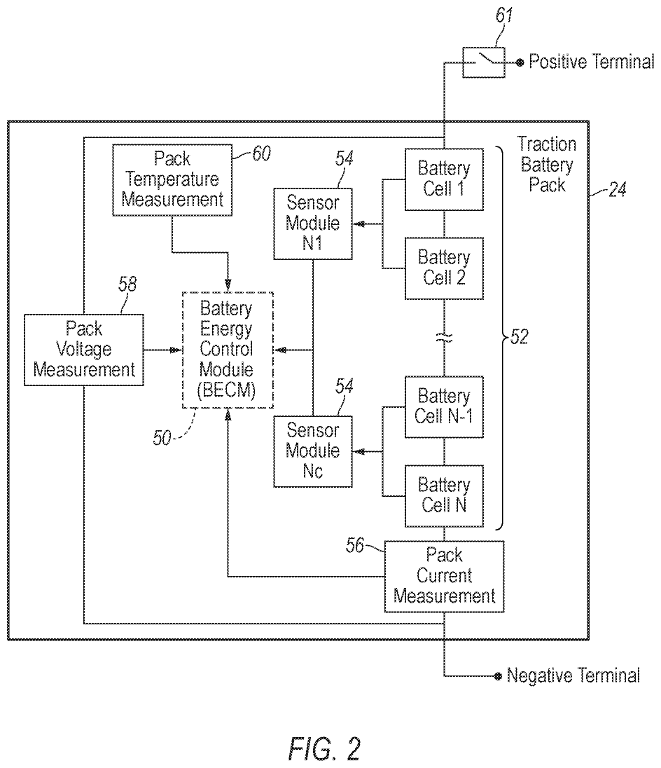

Referring now to FIG. 2, with continual reference to FIG. 1, a block diagram of an arrangement for BECM 50 to monitor traction battery 24 is shown. As indicated in FIG. 2, traction battery 24 is comprised of a plurality of battery cells 52. Battery cells 52 are physically connected together (e.g., connected in series as shown in FIG. 2) between a positive terminal (i.e., a positive power bus) and a negative terminal (i.e., a negative power bus). More generally, traction battery 24 comprises one or more battery cell modules that are electrically connected together, and each battery cell module comprises one or more battery cells 52 that are electrically connected together. For simplicity of discussion, it is assumed that the battery cell module(s) are connected in series and that battery cells 52 are connected in series.

BECM 50 is operable to monitor pack level (i.e., traction battery level) characteristics of traction battery 24 such as battery current 56, battery voltage 58, and battery temperature 60. Battery current 56 is the current outputted (i.e., discharged) from or inputted (i.e., charged) to traction battery 24. Battery voltage 58 is the terminal voltage of traction battery 24.

BECM 50 is also operable to measure and monitor battery cell level characteristics of battery cells 52 of traction battery 24. For example, terminal voltage, current, and temperature of one or more of battery cells 52 may be measured. BECM 50 may use a battery sensor 54 to measure the battery cell level characteristics. Battery sensor 54 may measure the characteristics of one or multiple battery cells 52. BECM 50 may utilize Nc battery sensors 54 to measure the characteristics of all battery cells 52. Each battery sensor 54 may transfer the measurements to BECM 50 for further processing and coordination. Battery sensor 54 functionality may be incorporated internally to BECM 50.

Traction battery 24 may have one or more temperature sensors such as thermistors in communication with BECM 50 to provide data indicative of the temperature of battery cells 52 of the traction battery for the BECM to monitor the temperature of the traction battery and/or the battery cells. BEV 12 may further include a temperature sensor to provide data indicative of ambient temperature for BECM 50 to monitor the ambient temperature.

BECM 50 controls the operation and performance of traction battery 24 based on the monitored traction battery and battery cell level characteristics. For instance, BECM 50 may use the monitored characteristics to detect operating characteristics of traction battery 24 (e.g., the capacity, the SOC, the power capability, etc., of the traction battery) such as for use in controlling the traction battery and/or BEV 12.

As shown in FIG. 2, one or more contactors 61 is provided to inhibit or permit electric current from traveling through the power buses to/from traction battery 24. Specifically, contactors 61 are operable to electrically decouple traction battery 24 from/to a charge/discharge system of BEV 12. The charge/discharge system includes components that either charge traction battery 24 or act as a load to draw electric power from the traction battery. Thus, the charge/discharge system may include inverter 26 and power conversion module 32 among other components. Contactors 61 may be placed in various suitable positions in BEV 12, such as between the positive power bus and inverter 26.

BECM 50 is configured to open or close contactors 61 based on a message/request from controller 48. Controller 48 is configured to detect when BEV 12 is to be turned ON (i.e., key on) or OFF (i.e., key off) based on an activation input (e.g., a user pressing a button associated with activating/deactivating the BEV). When BEV 12 is to be turned ON, controller 48 provides an activation request to BECM 50 to close contactors 61, thereby coupling traction battery 24 to the charge/discharge system. When BEV 12 is to be turned OFF, controller 48 provides a deactivation request to BECM 50 to open contactors 61, thereby decoupling traction battery 24 from the charge/discharge system. In addition, controller 48 is configured to have BECM 50 close contactors 61 by sending the activation request when traction battery 24 is to be charged or to be discharged. Likewise, controller 48 is configured to have BECM 50 open contactors 61 by sending the deactivation request when traction battery 24 is not to be charged or discharged.

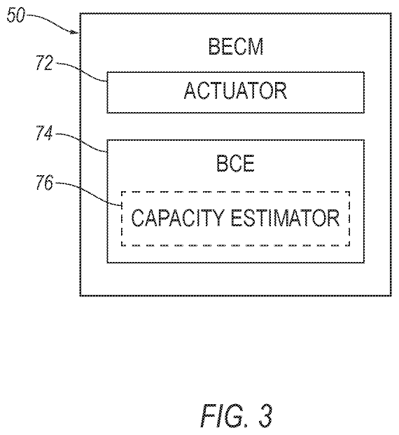

Referring now to FIG. 3, a block diagram of BECM 50 is shown. BECM 50 includes an actuator 72 for operating contactors 61 in the closed/opened positions. BECM 50 further includes a battery characteristics estimator (BCE) 74. BCE 74 is configured to estimate operational characteristics of traction battery 24 including the capacity, the SOC, and the power capability of the traction battery. BCE 74 includes a capacity estimator 76 to estimate the capacity of traction battery 24. The operation carried out by BCE 74 (more generally, BECM 50) in estimating the capacity of traction battery 24 will now be described.

The capacity Q of traction battery 24 can be estimated as follows:

$$Q = \frac{\sum I Δ t}{( {SOC}_{i} - {SOC}_{f} )} \qquad ( 1 )$$

I is the current of traction battery 24, Δt is is the sampling time, SOCᵢ is the initial SOC of the traction battery, and SOC_{f} is the final SOC of the traction battery.

Per the equation (1), the estimate of the capacity of traction battery 24 depends on the SOC of the traction battery. Accordingly, if the SOC of traction battery 24 is known well enough (particularly, if each of the initial SOC and the final SOC are known well enough), then the estimated capacity will be accurate. Conversely, if the SOC of traction battery 24 is not known well enough, then the estimated capacity will not be as accurate. That is, the accuracy of the estimation of the capacity depends on the accuracy of the SOC.

The accuracy of the SOC depends on the amount of uncertainty (i.e., error) of the SOC. A SOC having less uncertainty has a higher accuracy than a SOC having a high uncertainty. As such, SOC uncertainty is an important component in estimating battery capacity. The charging and discharging of traction battery 24 is controlled depending on operational characteristics of the traction battery including its capacity and/or other operational characteristics dependent on the capacity. Thus, accurate capacity estimation is highly desired and therefore estimation of the SOC with less uncertainty is highly desired. In general, SOC uncertainty estimation influences the overall capacity estimation to link a tighter bound to better capacity estimation accuracy, faster updating rate, better DTE (distance-to-empty) and power charge/discharge limits calculations, etc.

An existing method of simply using a SOC-OCV (open-circuit voltage) curve slope and voltage measurement error to estimate the SOC is normally not the best representation of the real SOC uncertainty. Accordingly, in this case, the capacity estimation may not be most accurate. For instance, the capacity estimation, such as using an adaptive filter approach, may not utilize individual capacity estimation efficiently because the filtering weight depends on SOC uncertainty estimation, among other factors.

The capacity with an overall estimation uncertainty (or error) bound can be expressed as:

$$Q = \frac{\sum I Δ t}{( {SOC}_{i} - {SOC}_{f} )} \pm ( \frac{\sum I Δ t}{( {SOC}_{i} - {SOC}_{f} )} ) \sqrt{{( \frac{U ( \sum I Δ t )}{\sum I Δ t} )}^{2} + {( \frac{\sqrt{{U ( {SOC}_{i} )}^{2} + {U ( {SOC}_{f} )}^{2}}}{( {SOC}_{i} - {SOC}_{f} )} )}^{2}} \qquad ( 2 )$$

The equation (2) is a summation of the capacity estimation from the equation (1) and an overall capacity uncertainty bound U(Q) that is represented by the following equation:

$$U ( Q ) = \pm ( \frac{\sum I Δ t}{( {SOC}_{i} - {SOC}_{f} )} ) \sqrt{{( \frac{U ( \sum I Δ t )}{\sum I Δ t} )}^{2} + {( \frac{\sqrt{{U ( {SOC}_{i} )}^{2} + {U ( {SOC}_{f} )}^{2}}}{( {SOC}_{i} - {SOC}_{f} )} )}^{2}} \qquad ( 3 )$$

The overall capacity uncertainty bound U(Q) is the amount of uncertainty (e.g., tolerance) of the capacity estimation.

The equation (2) pertains to a methodology to estimate both the capacity Q and the uncertainty in the capacity estimation U(Q).

The overall capacity uncertainty bound U(Q) provides an overall estimation error bound for capacity estimation. As set forth in the equation (3), the overall capacity uncertainty bound U(Q) includes the previously introduced factors: ΣIΔt, which is the integration of current (net ampere-hour throughput) of traction battery 24 between contactor close event #1 and contactor close event #2; SOCᵢ, which is the SOC at the contactor close event #2; and SOC_{f}, which is SOC at the contactor close event #1. ΣIΔt is measured by sensing the current during the two close events. SOCᵢ, and SOC_{f}, which depend on the voltage and temperature of traction battery 24, are obtained via a SOC-OCV lookup table.

As further set forth in the equation (3), the overall capacity uncertainty bound U(Q) further includes the following factors: U(ΣIΔt), which is the uncertainty in the net ampere-hour throughput measurement; U(SOCᵢ), which is the uncertainty in the SOC-OCV lookup at contactor close event #2; and U(SOC_{f}), which is the uncertainty in the SOC-OCV lookup at contactor close event #1.

From the above equations, a ratio of the overall capacity uncertainty bound U(Q) to the capacity Q as a percentage is represented by the following equation:

$$\frac{U ( Q )}{Q} = 100 * \sqrt{{( \frac{U ( \sum I Δ t )}{\sum I Δ t} )}^{2} + {( \frac{\sqrt{{U ( {SOC}_{i} )}^{2} + {U ( {SOC}_{f} )}^{2}}}{( {SOC}_{i} - {SOC}_{f} )} )}^{2}} \qquad ( 4 )$$

As set forth, the amount of the overall capacity uncertainty bound U(Q) depends on the amount of uncertainty in the uncertainty components U(ΣIΔt), U(SOCᵢ), and U(SOC_{f}).

In accordance with the present disclosure, BECM 50 is operable to reduce the amount of uncertainty in the uncertainty components U(SOCᵢ) and U(SOC_{f}). That is, BECM 50 is operable to estimate a tighter bound for SOC error and thereby reduce the SOC uncertainty. The SOC uncertainty “U(SOC)”, or the SOC uncertainty bound, is the amount of uncertainty of U(SOCᵢ) and U(SOC_{f}) taken individually and/or in combination. BECM 50 estimates a tighter (i.e., refined) SOC uncertainty bound for more accurate estimation of the capacity of traction battery 24.

As indicated above, an existing method for SOC uncertainty estimation involves simply using a SOC-OCV curve slope and voltage measurement error to estimate the SOC. In this regard, the SOC uncertainty U(SOC) is calculated using the slope from the SOC-OCV curve at the given OCV estimation with consideration of the uncertainty in the OCV and the SOC. This is represented by the following equation:

$$Δ SOC = \frac{\partial S O C}{\partial OC V} * Δ OC V \qquad ( 5 )$$

ΔSOC is the SOC uncertainty,

$$\frac{\partial S O C}{\partial OC V}$$

is the slope of the SOC-OCV curve, and ΔOCV is the OCV uncertainty.

The existing method considers that SOC uncertainty is bounded by OCV error and the OCV-SOC curve slope. However, the existing method may produce a larger SOC estimation uncertainty bound compared with the true bound of the SOC uncertainty as the existing method does not further consider the following SOC uncertainty factors.

One SOC uncertainty factor not considered is that SOC uncertainty is between (−100%, 100%) as the SOC is defined as a percentage falling within a range of 0%-100%. Another SOC uncertainty factor not considered is that SOC uncertainty is bounded by known capacity error (either from BOL (begin-of-life or after certain operations), current integration error, and initial SOC error. Another SOC uncertainty factor not considered is that SOC uncertainty should be taken with voltage measurement error evenly distributed within its own error bound, and correspondingly, SOC uncertainty should come from average SOC error, based on OCV-SOC lookup table, and averaging on the potential OCV value distribution. Another SOC uncertainty factor not considered is that SOC uncertainty should never be higher compared with the cumulative error of the last SOC uncertainty, and the total ampere-hour integration based SOC change uncertainty.

BECM 50 in accordance with the present disclosure considers at least two or more of such SOC uncertainty factors in estimating the SOC uncertainty. Each SOC uncertainty factor is associated with its own SOC error bound. BECM 50 uses the minimal of all of the SOC error bounds in estimating the SOC uncertainty.

In one implementation, BECM 50 considers the SOC uncertainty factor considered by the existing method and at least one the above-noted SOC uncertainty factors not considered by the existing method. In another implementation, BECM 50 considers the SOC uncertainty factor considered by the existing method and at least all of the above-noted SOC uncertainty factors not considered by the existing method.

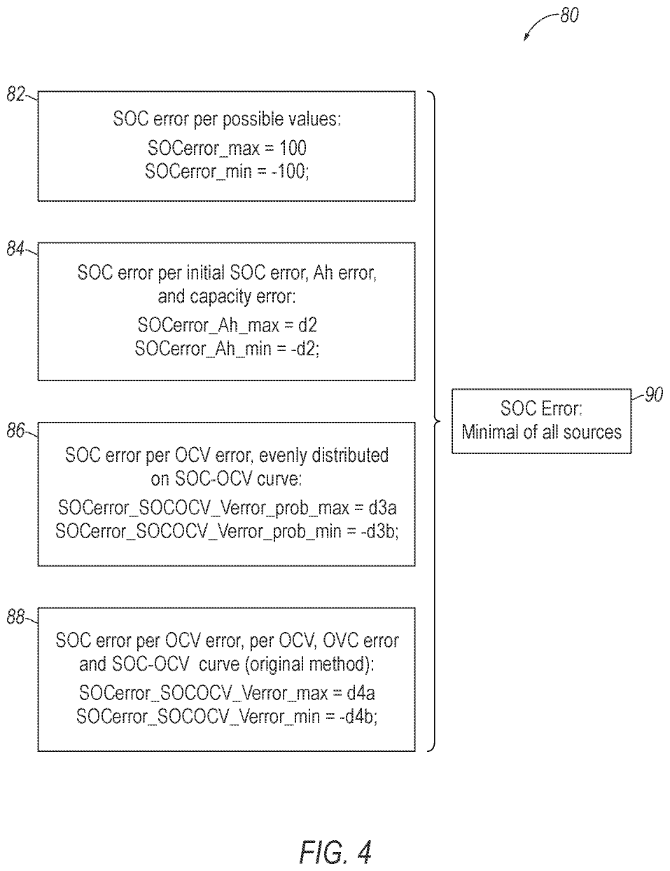

Referring now to FIG. 4, a block diagram 80 depictive of SOC uncertainty factors considered by BECM 50 in estimating the SOC uncertainty bound for the SOC of traction battery 24 is shown. As described, in overview, there are different ways of establishing SOC error bound at any given time. A first SOC uncertainty factor is that at any moment SOC error cannot exceed +/−100% due to the definition of SOC, indicated by block 82. A second SOC uncertainty factor is that SOC error cannot be more than the initial SOC error, capacity error, and ampere-hour integration error combined (in a statistics way), indicated by block 84. A third SOC uncertainty factor is that SOC error, per the SOC-OCV curve, can be established using an evenly-distributed OCV error at a given OCV value, and averaged out, indicated by block 86. A fourth SOC uncertainty is that SOC error can be established using the SOC-OCV curve at the given OCV value, OCV error, and SOC-OCV slope value, indicated by block 88. The overall SOC error cannot exceed any of these SOC error bounds, indicated by block 90.

In further detail, the first SOC uncertainty factor (i.e., potential error bound #1) pertains to adding higher and lower physically possible bounds for the SOC uncertainty estimation. This is the easiest SOC uncertainty factor to implement. For the SOC estimation at any time, the SOC uncertainty cannot have an error that is beyond +/−100%. Accordingly, BECM 50 considers this limit for SOC calculations. As indicated in block 82, the first SOC error bound is denoted as [−d1, d1], where d1=SOCerror_max=100%, and −d1=SOCerror_min=−100%.

The second SOC uncertainty factor (i.e., potential error bound #2) pertains to the SOC error per the initial SOC error, Ah error, and capacity error. There are use cases where traction battery 24 starts its operation with an accurate initial SOC value. For example, (even for lithium-iron phosphate (LFP) traction batteries), if the discharge is starting from a relatively high SOC or if charging is starting from a relatively low SOC after rest, then the initial SOC error can be within, e.g., 2% of true value, of course depending on voltage measurement accuracy. For such use case, it is possible to find another SOC error bound. Ah error has been established as, e.g., 1%. Capacity error should be well within, e.g., 30% of true value. This can be reduced even more if usage of traction battery 24 is considered. Because traction battery 24 starts with BOL accuracy (of capacity, which is within, e.g., 2%), and with the assumption that the algorithm has established capacity estimation within a desired bound, BECM 50 sets the capacity error at 5%.

This SOC uncertainty factor percentage “d” can be quantified per the following equation:

$$d = \sqrt{{( RUSOC\_init )}^{2} + {( R U A h )}^{2} + {( R U C a p )}^{2}} \qquad ( 6 )$$

“RU” is the relative uncertainty.

Using the noted values for each RU component, this SOC uncertainty factor percentage “d” is calculated per the following equation:

$$d = \sqrt{{( 0.02 )}^{2} + {( 0.01 )}^{2} + {( 0.05 )}^{2}} = 0.0548 ( or 5.48 \% ) \qquad ( 7 )$$

The value of this percentage factor can then be transformed into “absolute error”: d2=f(OCV)*d, for example if SOC as looked up from OCV is 70%. In this case, as indicated in block 84, the second SOC error bound is denoted as [−d2, d2], where d2=SOCerror_Ah_max=5.48%*0.70=3.84%, and −d2=SOCerror_Ah_min=−3.84%.

The third SOC uncertainty factor (potential error bound #3) pertains to SOC error based on the assumption of OCV error even distribution and the SOC-OCV curve. It is understood that for the SOC-OCV curve (the one-to-one relationship normally exhibited for certain types of traction batteries at SOC range from 0% to 100%) may have different slopes at different SOC values (or OCV values). BECM 50 uses the SOC-OCV curve slope to find the worst case slope and this value is used as a “divider” to get the evenly distributed OCV values if needed. This represents the worst case scenario. Once an OCV, and an error bound, are established based on the distribution grid size, BECM 50 can calculate all SOC values with respect to the “reference” SOC (that is based on OCV value itself). BECM 50 takes the average of all SOC errors on one side, the positive side SOC error and the negative side SOC error can be calculated as above. As indicated in block 86, the third SOC error bound is denoted as [−d3b, d3a], where d3a=SOCerror_SOCOCV_Verror_prob_max, and −d3b=SOCerror_SOCOCV_Verror_prob_min (these two percentage values d3a and −d3b may be different in magnitude).

An example of calculating the third SOC error bound is as follows. This example assumes that using a pertinent SOC-OCV curve the following information is obtained: estimated OCV=3.32 V (60.999% SOC); OCV estimation error=+/−12 mV; range of OCV (with uncertainty)=[3.308, 3.332]; minimal slope=1 mV/1% SOC; and calculated SOC error per OCV distribution: [−7.6667 −5.0000 −3.0000 −2.3333 −1.6667 −1.0000 −0.8571 −0.7143 −0.5714 −0.4286 −0.2857 −0.1429 −0.0000 0.1429 0.2857 0.4286 0.5714 0.7143 0.8571 1.0000 1.1538 1.3077 1.4615 1.6154 1.7692]. In this case, the SOC uncertainty (positive, average)=0.9423%; and the SOC uncertainty (negative, average)=−1.9722%. As such, the SOC uncertainty bound due to SOC-OCV slope changes and OCV measurement uncertainty is [−1.9722%, 0.9423%].

The fourth SOC uncertainty factor (potential error bound #4) pertains to the existing method involving using a SOC-OCV curve slope and voltage measurement error to estimate the SOC. As such, the SOC error can be established using the SOC-OCV curve at the given OCV value, OCV error, and SOC-OCV slope value per the above equation (5). As indicated in block 88, the fourth SOC error bound is denoted as [−d4b, d4a], where d4a=SOCerror_SOCOCV_Verror_max, and −d4b=SOCerror_SOCOCV_Verror_min (these two percentage values d4a and −d4b may be different in magnitude).

In estimating the SOC uncertainty, BECM 50 uses the minimal SOC error bound based on all of the first, second, third, and fourth SOC uncertainty factors, as indicated in block 90. This minimal SOC error bound is the SOC uncertainty bound. Compared with the existing method, in which the SOC uncertainty bound is the fourth SOC error bound per the fourth SOC uncertainty factor, the SOC uncertainty bound is estimated based on all of the first, second, third, and fourth SOC uncertainty factors. In practice, these four SOC uncertainty factors considered together result in BECM 50 estimating a SOC uncertainty bound that is smaller than the fourth SOC error bound. As such, compared with the existing method, BECM 50 estimates a refined SOC uncertainty bound (i.e., a more limited or tighter SOC uncertainty bound that is smaller than the fourth SOC error bound) for the SOC of traction battery 24. In turn, BECM 50 estimates the capacity of traction battery 24 according to the SOC of the traction battery with the estimated SOC uncertainty bound and controls the traction battery and/or BEV 12 based on the capacity. Of course, in relatively rare situations, the fourth SOC error bound is the lowest SOC uncertainty bound (i.e., the first, second, third, and fourth SOC uncertainty factors considered together result in BECM 50 estimating a SOC uncertainty bound that is equal to the fourth SOC error bound).

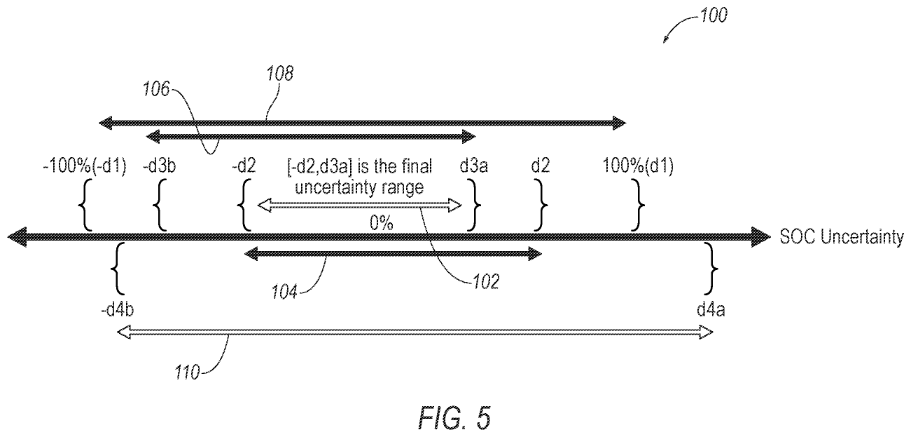

Referring now to FIG. 5, with continual reference to FIG. 4, a graph 100 of exemplary values for the SOC uncertainty factors considered by BECM 50 in estimating the SOC uncertainty bound is shown. Graph 100 is to explain in further detail how BECM 50 uses the minimal SOC error bound based on all of the first, second, third, and fourth SOC uncertainty factors in estimating the SOC uncertainty bound. In operation, once all possible sources of SOC uncertainties are enlisted and calculated (i.e., d1, −d1, d2, −d2, d3a, −d3b, d4a, and −d4b), the least amount of SOC uncertainty (from each positive/negative percentage side) can be used to estimate the SOC uncertainty. On the positive percentage side, the SOC uncertainty: USOC+=min (d1, d2, d3a, d4a). On the negative percentage side, the SOC uncertainty: USOC−=max (−d1, −d2, −d3b, −d4b). The final SOC uncertainty range: final USOC=[USOC−, USOC+]. The absolute SOC uncertainty: absolute USOC=[−max(abs(USOC−), USOC+), max(abs(USOC−), USOC+)]. These values are “absolute error” in the sense that it is true SOC unit percentage and not relative to some reference value.

As shown in graph 100, for these exemplary values for the SOC uncertainty factors, the least amount of SOC uncertainty on the positive percentage side is d3a, and the least amount of SOC uncertainty on the negative percentage side is-d2. Hence, the final SOC uncertainty range is [-d2, d3a], indicated by range 102. Note that the final SOC uncertainty range is lower than each of the SOC uncertainty ranges [d2, −d2], [d3a, −d3b], [d1, −d1], and [d4a, −d4b], respectively indicated by ranges 104, 106, 108, and 110.

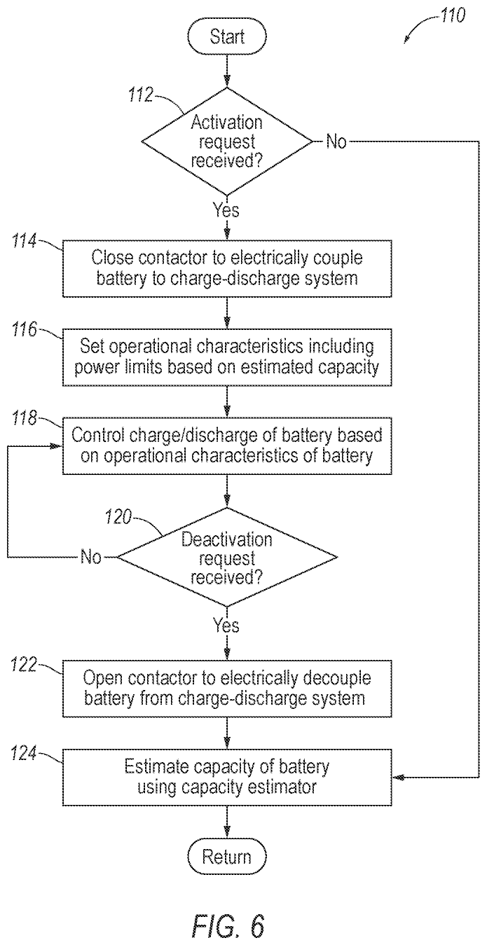

Referring now to FIG. 6, with continual reference to FIGS. 3, 4, and 5, a flowchart 110 depicting operation of BECM 50 in controlling traction battery 24 and/or BEV 12 based on the capacity of the traction battery according to the SOC of the traction battery with the estimated SOC uncertainty bound is shown. In operation, BECM 50 determines if an activation request is received, as indicated by decision block 112. If received, BECM 50 closes contactors 61 to electrically couple traction battery 24 to the charge/discharge system of BEV 12 (i.e., key on event), as indicated by block 114. BECM 50 then sets operational characteristics including power limits based on the capacity of traction battery 24 estimated after the last deactivation of BEV 12, as indicated by block 116. In turn, BECM 50 controls the charge/discharge of traction battery 24 based on the operational characteristics of the traction battery, as indicated by block 118.

BECM 50 continues with the controlling of the charge/discharge of traction battery 24 until a deactivation request is received, as indicated by decision block 120. Once the deactivation request is received, BECM 50 opens contactors 61 to electrically decouple traction battery 24 from the charge/discharge system (i.e., key off event), as indicated by block 122. BECM 50 then estimates the capacity of traction battery 24 using capacity estimator 76 as described above, as indicated by block 124. Further, as indicated by flowchart 110, BECM 50 may estimate the capacity of traction battery 24 when no activation request is received.

As described, in accordance with the present disclosure, BECM 50 considers various SOC uncertainty factors in estimating the uncertainty of the SOC of traction battery 24 for use in estimating the capacity of the traction battery. By considering various SOC uncertainty factors, the estimate of the SOC uncertainty is typically tighter (i.e., more limited or reduced) than the SOC uncertainty estimated with consideration of just one of the SOC uncertainty factors. Particularly, the estimate of the SOC uncertainty is typically tighter than the SOC uncertainty estimated with consideration of just the SOC uncertainty factor pertaining to an existing method involving the SOC-OCV slope and voltage uncertainty. In addition to the SOC uncertainty factor pertaining to the existing method, other SOC uncertainty factors considered by BECM 50 include factors involving voltage measurement distribution, actual SOC-OCV curve differences at different voltage values, physically possible values of SOC uncertainty, and operational SOC uncertainty.

In sum, BECM 50 provides the benefit of obtaining tighter SOC uncertainty for capacity estimation. Compared with the existing method, the approach implemented by BECM 50 may drastically reduce SOC estimation uncertainty based on the given battery cell properties, OCV measurement (estimation), and the estimation uncertainty associated with it. In particular, a reduced SOC estimation uncertainty may lead to fewer number of samples used for accurately estimating battery capacity and may lead to a larger weight used in adaptive filter for battery capacity estimation. Separate from capacity estimation, a reduced SOC estimation uncertainty may lead to better use of OCV estimation for SOC initialization purpose. This will in turn support more accurate SOC and DTE estimation for traction battery controls.

While exemplary embodiments are described above, it is not intended that these embodiments describe all possible forms of the present disclosure. Rather, the words used in the specification are words of description rather than limitation, and it is understood that various changes may be made without departing from the spirit and scope of the present disclosure. Additionally, the features of various implementing embodiments may be combined to form further embodiments of the present disclosure.

What is claimed is:

1. A system comprising:
a battery having a state-of-charge (SOC) with a SOC uncertainty; and
a controller configured to charge and discharge the battery based on a capacity of the battery according to the SOC with a bound of the SOC uncertainty, the bound of the SOC uncertainty being based on consideration of multiple SOC uncertainty factors to thereby be reduced relative to being based on consideration of less than all of the SOC uncertainty factors.

2. The system of claim 1 wherein:
each SOC uncertainty factor is associated with its own bound of the SOC uncertainty; and
the bound of the SOC uncertainty is the smallest bound of the SOC uncertainty factors.

3. The system of claim 1 wherein:
each SOC uncertainty factor is associated with its own bound of the SOC uncertainty and the bound of each SOC uncertainty factor is a range between a negative value and a positive value; and
the bound of the SOC uncertainty is a range between (i) the negative value having a lowest magnitude amongst the negative values and (ii) the positive value having a lowest magnitude amongst the positive values.

4. The system of claim 1 wherein:
a first one of the SOC uncertainty factors is indicative of the SOC uncertainty based on an uncertainty of a voltage measurement of the battery and a SOC-OCV (open-circuit voltage) table that are used together in estimating the SOC; and
the bound of the SOC uncertainty is reduced relative to being based on consideration of just the first one of the SOC uncertainty factors.

5. The system of claim 4 wherein:
another one of the SOC uncertainty factors is indicative of the SOC uncertainty based on a range of an amount of SOC uncertainty that is physically possible.

6. The system of claim 4 wherein:
another one of the SOC uncertainty factors is indicative of the SOC uncertainty based on an uncertainty of an ampere-hour integration measurement that is used in estimating the SOC.

7. The system of claim 4 wherein:
another one of the SOC uncertainty factors is indicative of the SOC uncertainty based on distributed voltage measurements of the battery that are used in estimating the SOC.

8. The system of claim 4 wherein:
another one of the SOC uncertainty factors is indicative of the SOC uncertainty based on an uncertainty pertaining to differences of a SOC-OCV (open-circuit voltage) table at different voltage measurements in which the SOC-OCV table with the different voltage measurements are used in estimating the SOC.

9. The system of claim 1 wherein:
the controller is further configured to detect and update the capacity while the battery is being charged and discharged.

10. The system of claim 1 wherein:
the battery is a traction battery of an electrified vehicle.

11. A method comprising:
detecting a state-of-charge (SOC) of a battery;
estimating an uncertainty of the SOC based on consideration of multiple SOC uncertainty factors;
detecting a capacity of the battery according to the SOC with the estimated SOC uncertainty, the estimated SOC uncertainty being reduced relative to an uncertainty of the SOC estimated based on consideration of less than all of the SOC uncertainty factors such that the capacity has reduced uncertainty; and
charging and discharging the battery based on the capacity.

12. The method of claim 11 wherein:
each SOC uncertainty factor is associated with a bound of the uncertainty of the SOC; and
the estimated SOC uncertainty is the smallest bound of the SOC uncertainty factors.

13. The method of claim 11 wherein:
each SOC uncertainty factor is associated with a bound of the uncertainty of the SOC and the bound of each SOC uncertainty factor is a range between a negative value and a positive value; and
the estimated SOC uncertainty is a range between (i) the negative value having a lowest magnitude amongst the negative values and (ii) the positive value having a lowest magnitude amongst the positive values.

14. The method of claim 11 wherein:
a first one of the SOC uncertainty factors is indicative of the uncertainty of the SOC based on an uncertainty of a voltage measurement of the battery and a SOC-OCV (open-circuit voltage) table that are used together in detecting the SOC; and
the estimated SOC uncertainty is reduced relative to the uncertainty of the SOC estimated based on consideration of just the first one of the SOC uncertainty factors.

15. The method of claim 14 wherein:
another one of the SOC uncertainty factors is indicative of the SOC uncertainty based on one of:
a range of an amount of SOC uncertainty that is physically possible;
an uncertainty of an ampere-hour integration measurement that is used in detecting the SOC;
distributed voltage measurements of the battery that are used in detecting the SOC; or
an uncertainty pertaining to differences of a SOC-OCV (open-circuit voltage) table at different voltage measurements in which the SOC-OCV table with the different voltage measurements are used in detecting the SOC.

16. An electrified vehicle comprising:
a traction battery; and
a controller configured to detect a state-of-charge (SOC) of the traction battery and to estimate an uncertainty of the SOC based on consideration of multiple SOC uncertainty factors, the estimated SOC uncertainty being reduced relative to an uncertainty of the SOC estimated based on consideration of less than all of the SOC uncertainty factors; and
the controller is further configured to charge and discharge the traction battery based on a capacity of the traction battery according to the SOC with the estimated SOC uncertainty.

17. The electrified vehicle of claim 16 wherein:
each SOC uncertainty factor is associated with a bound of the uncertainty of the SOC; and
the estimated SOC uncertainty estimated by the controller is the smallest bound of the SOC uncertainty factors.

18. The electrified vehicle of claim 16 wherein:
each SOC uncertainty factor is associated with a bound of the uncertainty of the SOC and the bound of each SOC uncertainty factor is a range between a negative value and a positive value; and
the estimated SOC uncertainty estimated by the controller is a range between (i) the negative value having a lowest magnitude amongst the negative values and (ii) the positive value having a lowest magnitude amongst the positive values.

19. The electrified vehicle of claim 16 wherein:
a first one of the SOC uncertainty factors is indicative of the uncertainty of the SOC based on an uncertainty of a voltage measurement of the battery and a SOC-OCV (open-circuit voltage) table that are used together in detecting the SOC; and
the estimated SOC uncertainty estimated by the controller is reduced relative to the uncertainty of the SOC estimated based on consideration of just the first one of the SOC uncertainty factors.

20. The electrified vehicle of claim 16 wherein:
a first one of the SOC uncertainty factors is indicative of the uncertainty of the SOC based on an uncertainty of a voltage measurement of the battery and a SOC-OCV (open-circuit voltage) table that are used together in detecting the SOC; and
a second one of the SOC uncertainty factors is indicative of the SOC uncertainty based on a range of an amount of SOC uncertainty that is physically possible; and
a third one of the SOC uncertainty factors is indicative of the SOC uncertainty based on an uncertainty of an ampere-hour integration measurement that is used in detecting the SOC.
